(19) United States
(12) Patent Application Publication
(10) Pub. No.: US 2021/0356636 A1
(43) Pub. Date: Nov. 18, 2021

(54) OPTICAL FILTER AND METHOD FOR MANUFACTURING THE OPTICAL FILTER

(71) Applicant: Wuhan China Star Optoelectronics Semiconductor Display Technology Co., Ltd., Wuhan, Hubei (CN)

(72) Inventor: Wenjing YU, Wuhan, Hubei (CN)

(21) Appl. No.: 16/484,287

(22) PCT Filed: Apr. 23, 2019
(86) PCT No.: PCT/CN2019/083880

§ 371 Date: Aug. 7, 2019

(30) Foreign Application Priority Data
Dec. 18, 2018 (CN) 201811548371.8

(51) Int. Cl. G02B 5/20

(52) U.S. Cl. CPC G02B 5/201

(57) ABSTRACT

An optical filter and a method for manufacturing the optical filter are provided. The optical filter includes a base substrate, a black matrix layer, and a color filter layer. The black matrix layer includes a lower, an intermediate, and an upper black matrix layers, and the intermediate layer is a plurality of particles. The black matrix has a plurality of layers of different structures, and light is absorbed when passing through different black matrix layers, reducing transmission of light, improving contrast of a display screen, and improving display effect.

### FIELD OF INVENTION

The present disclosure relates to the field of display technologies, and in particular, to an optical filter and a method for manufacturing the optical filter.

### BACKGROUND OF INVENTION

An organic light emitting diode (OLED) has the advantages of self-illumination, wide viewing angle, high contrast, low power consumption and simple process, and has become the mainstream product in the entire consumer market.

When other display devices such as mobile devices are used, the effect of the display on the screen affects the user's experience. When used in a room with weak light, the effect of the display on the screen is better. However, when the display device is used in some places, for example, outdoors, where the light is relatively strong, the light causes the contrast of the device to decrease and the display effect of the screen to decrease. At present, a polarizer (POL) is often attached to the top of the screen. However, while absorbing the external sunlight, the POL also absorbs about 55% of the light emitted by the OLED. Therefore, the luminosity of most display devices is lowered, and the contrast of the display device is lowered. Or, when the device contrast is raised, a low-temperature black matrix (BM) is filled between the color filters (CF) so that the sunlight in the non-light-emitting area is also absorbed; but, owing to the fact that this method has process problems, the low temperature BM will cause the optical density (OD) value to be insufficient, and it will not completely absorb the external sunlight and so the sunlight will penetrate again.

### SUMMARY OF INVENTION

Technical problems: The contrast of the screen of the existing display device is relatively low, the loss of light in the optical filter in the OLED display panel is large, and the optical density at the low temperature BM is low and so the external sunlight cannot be completely absorbed, which cannot meet the needs of consumers. Further improvements are needed.

Technical solutions: In order to solve the above technical problems, the technical solutions provided by the present disclosure are as follows:

According to a first aspect of an embodiment of the present disclosure, an optical filter is provided, comprising: a base substrate, and a black matrix layer and a color filter layer on the base substrate; the black matrix layer is disposed between any two of color filters of the color filter layer, each of the color filters is disposed only on one of pixel units corresponding to the color filters, the black matrix layer includes a lower black matrix layer, an intermediate layer and an upper black matrix layer, the intermediate layer of the black matrix layer is composed of a plurality of particles, and a material of each particle is a light-scattering black sphere.

According to an embodiment of the present disclosure, the black matrix layer has a thickness smaller than the color filter layer.

According to an embodiment of the present disclosure, the material of the particles is a light-absorbing material.

According to an embodiment of the present disclosure, each particle has a diameter of less than 1000 nm.

According to an embodiment of the present disclosure, the optical filter is disposed on a touch panel.

According to a second aspect of the present disclosure, an optical filter is also provided. The optical filter comprises:

a base substrate, and

a black matrix layer and a color filter layer on the base substrate;

the black matrix layer is disposed between any two of color filters of the color filter layer, each the color filters is disposed only on one of pixel units corresponding to the color filters, the black matrix layer includes a lower black matrix layer, an intermediate layer and an upper black matrix layer, and the intermediate layer of the black matrix layer is composed of a plurality of particles.

According to an embodiment of the present disclosure, the black matrix layer has a thickness smaller than the color filter layer.

According to an embodiment of the present disclosure, a material of the particles is a light-absorbing material.

According to an embodiment of the present disclosure, the material of each particle is a light-scattering black sphere.

According to an embodiment of the present disclosure, each particle has a diameter of less than 1000 nm.

According to an aspect of collaboration manufacturers of the present disclosure, a method for manufacturing an optical filter is also provided, comprising steps as follows:

S100: arranging a color filter layer on a base substrate, where each of the color filters of the color filter layer is disposed only on one of pixel units corresponding to the color filters; and

S101: disposing a black matrix layer on the base substrate wherein the black matrix layer has openings and is located between any two of color filters of the color filter layer on the base substrate.

According to an embodiment of the present disclosure, step S101 further includes:

S201: first, disposing a lower black matrix layer;

S202: further disposing a particle layer on the lower black matrix layer; and

S203: further disposing a black matrix layer on the particle layer.

Beneficial effects: In summary, the beneficial effects of the present disclosure are as follows:

By modifying the optical filter and the black matrix in the existing display panel, each of the color filters of the present disclosure is disposed only on one of the R, G, and B pixel units correspondingly. In the new black matrix, there are three layers of structural characteristics, and the particles in the intermediate layer can further scatter and absorb the light, thereby reducing the emission and re-ejecting of light, thereby improving the contrast of the display panel, and thereby improving the display effect of the display panel.

### DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled in the art based on these drawings without paying any creative effort.

FIG. 1 is a schematic structural view of an optical filter and a black matrix module in a first embodiment of the present disclosure;

FIG. 2 is a schematic structural view of an optical filter and a black matrix module in a second embodiment of the present disclosure;

FIG. 3 is an enlarged schematic view of a black matrix layer in an embodiment of the present disclosure; and

FIG. 4 is a flow chart of a process for manufacturing an optical filter of the present disclosure.

### DETAILED DESCRIPTION OF PREFERRED EMBODIMENTS

The technical solutions in the embodiments of the present disclosure will be clearly and completely described in the following with reference to the accompanying drawings in the embodiments. It is apparent that the described embodiments are only a part of the embodiments of the present disclosure, and not all of them. All other embodiments obtained by those skilled in the art based on the embodiments of the present disclosure without paying any creative effort are the scope of the disclosure.

In the present disclosure, it is to be understood that such orientation or positional relationship of the indications as the terms ‘center’, ‘longitudinal’, ‘lateral’, ‘length’, ‘width’, ‘thickness’, ‘upper’, ‘lower’, ‘front’, ‘post’, ‘left’, ‘right’, ‘vertical’, ‘level’, ‘top’, ‘bottom’, ‘inside’, ‘outside’, etc. are the orientation or positional relationship based on the drawings, which are merely for convenience of description of the present disclosure and simplified description. Moreover, the terms “first” and “second” are used for descriptive purposes only and are not to be construed as indicating or implying a relative importance or implicitly indicating the number of technical features indicated. Thus, features defining “first” or “second” may include one or more of the described features either explicitly or implicitly. In the description of the present disclosure, the meaning of “a plurality” is two or more unless clearly and specifically defined otherwise.

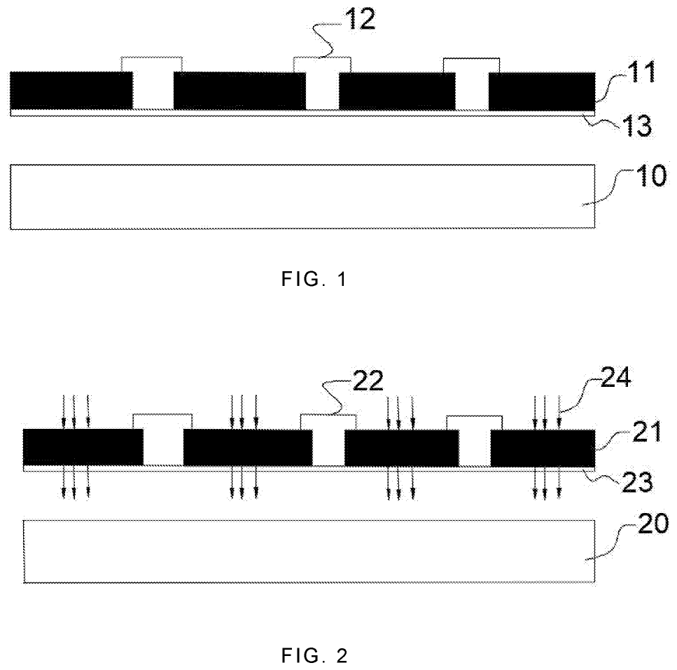

In this embodiment, as shown in FIG. 1, FIG. 1 is a schematic structural view of an optical filter and a black matrix module according to the present disclosure, including a substrate 10, a black matrix 11, color filters 12, and a base substrate 13. The black matrix 11 and the color filters 12 are disposed on the base substrate 13, each of the color filters 12 is disposed only on one of R, G, and B pixel units correspondingly, and the black matrix 11 is disposed between any two of the color filters 12. Among them, in a specific display product, other devices such as a thin film transistor may be disposed between the substrate 10 and the base substrate 13. The color filters 12 are a light-emitting area and are a color filter of the R, G, and B types, respectively. Different from the conventional monolithic color filter, each of the color filters 12 in the present disclosure is disposed only on one of the R, G, and B pixel units correspondingly, and no color filter 12 is disposed in other areas. In this way, after the light is incident, it will be filtered, and different colors of light will be obtained. The black matrix 11 is a non-light-emitting area, which is sequentially disposed between the color filters 12, thereby absorbing the incident light.

As shown in FIG. 2, FIG. 2 is a schematic view of an optical filter and a black matrix module structure when light is incident in an embodiment of the present disclosure, including a substrate 20, a black matrix 21, color filters 22, a base substrate 23, and light rays 24. The black matrix 21 and the color filters 22 are disposed on the base substrate 23, one of the color filters 22 is disposed only on one of the R, G, and B pixel units correspondingly, and the black matrix 21 is disposed between any two of the color filters 22. The thickness of the black matrix 21 is smaller than the thickness of the color filter 22. Normally, the non-light-emitting area, that is, black matrix 21, will absorb or substantially absorb most of the incident light rays 24 to reduce the influence of the passing light rays 24 on the display screen contrast. The absorption of light by the black matrix 11 directly affects the contrast of the display. If the light passing through the black matrix 11 is too much, the contrast of the display screen will be low, and the display effect will be poor. Therefore, it is necessary to make the light as completely absorbed as possible when passing through the black matrix 21, or only a small portion of the light can pass through the black matrix 21.

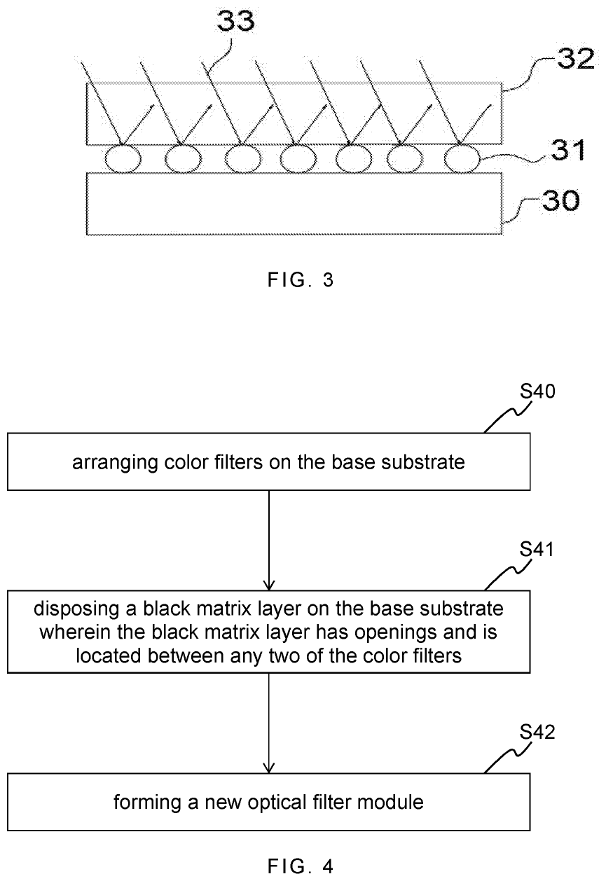

As shown in FIG. 3, FIG. 3 is an enlarged schematic view of a black matrix structure in an embodiment of the present disclosure, including a lower black matrix layer 30, an intermediate particle layer 31, an upper black matrix layer 32, and external light rays 33. The intermediate particle layer 31 is disposed on the lower black matrix layer 30, and the upper black matrix layer 32 is disposed on the intermediate particle layer 31. In order to ensure that light can be maximally absorbed by the black matrix, the present disclosure discloses a black matrix layer of a three-layer structure. When the external light 33 passes through the upper black matrix 32 of the non-light-emitting area, a part of the external light is absorbed, and another portion of the external light 33 that is not absorbed reaches the intermediate particle layer 31. The material of the intermediate particles is a light-absorbing material, which may be some black spheres. The diameter of the sphere is less than 1000 nm. At the same time, the black spheres of the particles can also reflect or scatter the light again, and the partially reflected or scattered light will enter the upper black matrix layer 32 again and be further absorbed. Still other portions of the light that are still not filtered by the intermediate particle layer 31 will then reach the lower black matrix layer 30. Such remaining light is further absorbed in the lower black matrix layer 30. Therefore, after the external light 33 passes through the upper black matrix layer 32, the intermediate particle layer 31, and the lower black matrix layer 30, only a small portion of the light remains, and most of the light is absorbed. The total thickness of the black matrix layer of the three-layer structure of the present disclosure is the same as the thickness of the black matrix layer manufactured in the prior art, so that the thickness of the black matrix layer structure of the present disclosure is not more than the thickness of the black matrix layer of the prior art, and at the same time, the light absorption effect of the black matrix layer is fully ensured. Compared with the general display, the display composed of the optical filter and the black matrix module of the present disclosure has higher contrast and better display effect.

The present disclosure further provides a display panel, which includes the optical filter of the above embodiment, and the display panel may be a touch panel or an OLED display panel.

The present disclosure also provides a method for manufacturing an optical filter, as shown in FIG. 4, and FIG. 4 is a flow chart of a process for manufacturing the optical filter of the present disclosure, Including steps as follows:

S40: arranging a color filter layer on the base substrate, where each of color filters of the color filter layer is disposed only on one of the pixel units corresponding to the color filters;

S41: disposing a black matrix layer on the base substrate wherein the black matrix layer has openings and is located between any two of color filters of the color filter layer on the base substrate; and

S42: forming a new optical filter module.

In the above step S41, when the black matrix is specifically manufactured, since the black matrix of the present disclosure has a multi-layer structure, step S41 further includes:

S51: First, disposing a lower black matrix layer;

S52: further disposing a particle layer on the lower black matrix layer; and

S53: further disposing a black matrix layer on the particle layer.

An optical filter, a display panel, and a method for manufacturing the optical filter provided by the embodiments of the present disclosure are described in detail above. The principles and implementations of the present disclosure have been described with reference to the specific examples, and the description of the above embodiments is only for the purpose of understanding the technical solutions and their core ideas of the present disclosure. It should be understood by those skilled in the art that they can still modify the technical solutions described in the foregoing embodiments or equivalently replace some of the technical features. These modifications and substitutions do not make the essence of the corresponding technical solutions depart from the scope of the technical solutions of the embodiments of the present disclosure.

What is claimed is:

1. An optical filter, comprising:
a base substrate; and
a black matrix layer and a color filter layer on the base substrate;
wherein the black matrix layer is disposed between any two of color filters of the color filter layer, each of the color filters is disposed only on one of pixel units corresponding to the color filters, the black matrix layer includes a lower black matrix layer, an intermediate layer and an upper black matrix layer, the intermediate layer of the black matrix layer is composed of a plurality of particles, and a material of each particle is a light-scattering black sphere.

2. The optical filter as claimed in claim 1, wherein the black matrix layer has a thickness smaller than the color filter layer.

3. The optical filter as claimed in claim 1, wherein the material of the particles is a light-absorbing material.

4. The optical filter as claimed in claim 3, wherein each particle has a diameter of less than 1000 nm.

5. The optical filter as claimed in claim 1, wherein the optical filter is disposed on a touch panel.

6. An optical filter, comprising:
a base substrate; and
a black matrix layer and a color filter layer on the base substrate;
wherein the black matrix layer is disposed between any two of color filters of the color filter layer, each of the color filters is disposed only on one of pixel units corresponding to the color filters, the black matrix layer includes a lower black matrix layer, an intermediate layer and an upper black matrix layer, and the intermediate layer of the black matrix layer is composed of a plurality of particles.

7. The optical filter as claimed in claim 6, wherein the black matrix layer has a thickness smaller than the color filter layer.

8. The optical filter as claimed in claim 6, wherein a material of the particles is a light-absorbing material.

9. The optical filter as claimed in claim 7, wherein the material of each particle is a light-scattering black sphere.

10. The optical filter as claimed in claim 8, wherein each particle has a diameter of less than 1000 nm.

11. A method for manufacturing an optical filter, comprising steps as follows:
S100: arranging a color filter layer on a base substrate, where each of color filters of the color filter layer is disposed only on one of pixel units corresponding to the color filters; and
S101: disposing a black matrix layer on the base substrate wherein the black matrix layer has openings and is located between any two of color filters of the color filter layer on the base substrate.

12. A method for manufacturing an optical filter as claimed in claim 11, wherein step S101 further includes:
S201: first, disposing a lower black matrix layer;
S202: further disposing a particle layer on the lower black matrix layer; and
S203: further disposing a black matrix layer on the particle layer.
